(19) United States
(12) Patent Application Publication
(10) Pub. No.: US 2024/0388019 A1
(43) Pub. Date: Nov. 21, 2024

(54) PRINTED CIRCUIT BOARD UNIT AND PRINTED CIRCUIT BOARD CONNECTION ELEMENT

(71) Applicant: HARTING Electronics GmbH, Espelkamp (DE)

(72) Inventors: Markus FRIESEN, Espelkamp (DE); Felix LOSKE, Minden (DE); Christian VOLLMER, Bielefeld (DE)

(21) Appl. No.: 18/689,374

(22) PCT Filed: Oct. 17, 2022
(86) PCT No.: PCT/DE2022/100762

§ 371 Date: Mar. 5, 2024

(30) Foreign Application Priority Data
Oct. 26, 2021 (DE) 10 2021 127 734.5

(51) Int. Cl. H01R 12/52; H05K 1/14

(52) U.S. Cl. CPC H01R 12/523; H05K 1/144; H05K 2201/0367; H05K 2201/042; H05K 2201/1059

(57) ABSTRACT

A printed circuit board unit includes includes at least one first and second printed circuit board and also a first connection element for mechanical and/or electrical connection between said at least one first and second printed circuit board. The connection element is in the form of a snap fastener, thereby creating a simple, robust and releasable connection between the two printed circuit boards.

The present invention relates to a printed circuit board unit and to a printed circuit board connecting element.

In modern electronic devices, a plurality of printed circuit boards are typically provided. These printed circuit boards must be electrically contacted and mechanically attached.

The German Patent and Trade Mark Office has searched the following prior art in the priority application for the present application: US 2009/0061656 A1, EP 1 157 448 B1, U.S. Pat. No. 4,813,129 A, DE 10 2014 116 236 A1 and US 2007/0026695 A1.

For this purpose, according to the prior art, printed circuit board connectors or plug-in connectors are typically provided. However, these have a considerable overall height.

The problem addressed by the present invention is thus that of providing a printed circuit board unit and a printed circuit board connecting element which allows a simple mechanical connection and a reduction in the overall height.

This problem is solved by a printed circuit board unit according to claim 1, by a printed circuit board connecting element according to claim 9, by the use of a push button as a connecting element according to claim 10 and by a plug-in connector according to claim 11.

A printed circuit board unit is thus provided with at least one first and second printed circuit board and at least one first connecting element for mechanical and/or electrical connection between the at least one first and second printed circuit board. The connecting element is in the form of a push button.

It is thus made possible to provide a simple, robust and detachable connection between the two printed circuit boards.

The push button can be formed in two parts and has a first and second push button element.

According to one aspect of the present invention, the push button comprises a depression, e.g. in the form of a dish, as a first push button element, and a corresponding projection (head) as a second push button element. The first push button element can be in the form of a female element, and the second push button element can be in the form of a male element. The depression or recess is arranged in or on a first printed circuit board, and the head is arranged in or on the second printed circuit board. When the two printed circuit boards are to be interconnected, then the head is placed in the dish. A mechanical connection between two printed circuit boards can thus be achieved. When the recess and the head are electrically conductive (e.g. metal) or made of an electrically conductive material, then an electrical connection can also be achieved.

According to another aspect of the present invention, a plurality of connecting elements can be provided. A first connecting element has first dimensions (with a first diameter and a first height). A second connecting element is also provided which has different dimensions, i.e. a different diameter and optionally a different height. It can thus be ensured that the two printed circuit boards are mounted so as to be protected against polarity reversal. This corresponds to the concept of poka-yoke.

The invention also relates to a printed circuit board connecting element, in particular to a printed circuit board plug-in connector. The printed circuit board connecting element has at least one push button having a first push button element (a depression e.g. in the form of a dish) and a second push button element (having a corresponding head). The dish can be attached in a first printed circuit board, and the head can be attached or integrated in or on a second printed circuit board.

The invention also relates to the use of a push button as a connecting element for a mechanical and/or electrical connection between at least one first and second printed circuit board. The push button comprises a first push button element which has a recess or depression. The push button further comprises a second push button element which has a corresponding projection so that the second push button element can be inserted in the first push button element. Preferably, the first and second push button elements are made of metal or a material which is electrically conductive at least in part, so that when inserting the second push button element in the first push button element, both a mechanical and an electrical connection can be achieved between a first and second printed circuit board.

According to one aspect of the invention, the first push button element (a dish) can be provided in or on a first printed circuit board. A second printed circuit board can comprise two second push button elements (heads) which are provided on both sides of the printed circuit board. Furthermore, a third printed circuit board can be provided with another first element. In order to achieve the printed circuit board unit, the first and third printed circuit boards with the first and second dishes can be placed over or in the corresponding heads on the second printed circuit board so that a printed circuit board unit with at least three printed circuit boards can be achieved. By using the push button as a connecting element between adjacent printed circuit boards, it is made possible to provide a cost-effective, robust and effective connection.

Furthermore, a printed circuit board unit with a low stack height which is easy to mount can be achieved.

According to one aspect of the present invention, the printed circuit board unit can consist of three printed circuit boards, wherein two printed circuit boards each have a dish, and a second printed circuit board can comprise for example two heads which are provided on opposite sides of the second printed circuit board. The second printed circuit board can then be used as a bridge connector.

A first head can thus be placed in a first dish of the first printed circuit board, and a second head can be placed in a second dish of the third printed circuit board so that the first and third printed circuit boards can be connected by means of a second printed circuit board which acts as a bridge for the mechanical and/or electrical connection.

According to one aspect of the present invention, a push button plug-in connector can be provided. The elements of the plug-in connector can each comprise elements of the push button.

The push button according to one aspect of the invention can be in the form of an S-spring push button, in the form of an annular-spring push button or in the form of a grip-fix push button.

The connecting element (e.g. the push button) can be designed to be electrically conductive at least in part. For example, the connecting element can be produced from metal or from an electrically conductive injection-molded plastics material.

According to one aspect of the invention, the printed circuit board can be in the form of a 3D-printed circuit board. For example, the printed circuit board can be produced in a 2C injection-molding process, wherein the connecting elements are placed in the tool and injection molded before or during the injection molding process. The connecting elements can be electrically conductive. The 2C injection-molding process can connect an insulating component to an electrically conductive component in order to be able to separate conductive regions from one another. The connecting elements can be in the form of a push button.

According to another aspect of the invention, the printed circuit board can be in the form of a 3D MID (mechatronic integrated device) printed circuit board. A printed circuit board can thus be achieved which has a three-dimensional design. In other words, the invention can be applied not only to a conventionally flat, planar printed circuit board, but also to a three-dimensional printed circuit board structure. In this case, the first and second push button elements can be integrated in the 3D-printed circuit boards during the injection-molding process. Contacting can then take place by means of conductive tracks on the surface of the injection-molded part.

According to another aspect of the present invention, the connecting element can be used to transfer energy and/or data. Alternatively, the connecting element can be used as the ground.

According to another aspect of the present invention, the first push button element has a thickness of 1-1.5 times the thickness of the printed circuit board, in particular a flat printed circuit board. This is advantageous because a construction of a printed circuit board unit comprising a plurality of printed circuit boards with a low overall height is thus made possible.

According to one aspect of the present invention, a printed circuit board unit comprising a first and second printed circuit board and a printed circuit board connecting element can be provided. The printed circuit board connecting element can be in the form of a bridge so that the first and second printed circuit board can be arranged side-by-side. The printed circuit board connecting element can comprise for example another printed circuit board having two second push button elements which can be mechanically and/or electrically coupled in first push button elements on the first and second printed circuit boards.

The connecting element is electrically conductive at least in part. For this purpose, the connecting element can comprise an electrically conductive material which is made possible for example by injection molding electrically conductive elements. Alternatively, a hybrid material, namely an electrically conductive plastics material with carbon fibers, can be achieved.

The dependent claims relate to additional embodiments of the invention.

Advantages and exemplary embodiments of the invention will be described in greater detail below with reference to the drawings.

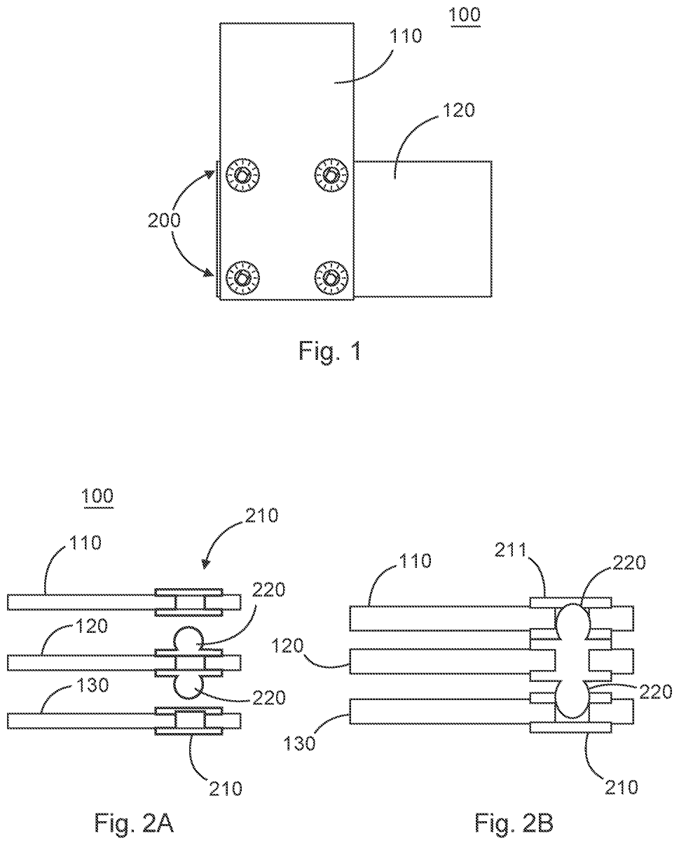

FIG. 1 is a schematic view of a printed circuit board unit according to one exemplary embodiment of the invention,

FIGS. 2A and 2B are each a schematic sectional view of a printed circuit board unit according to a second exemplary embodiment,

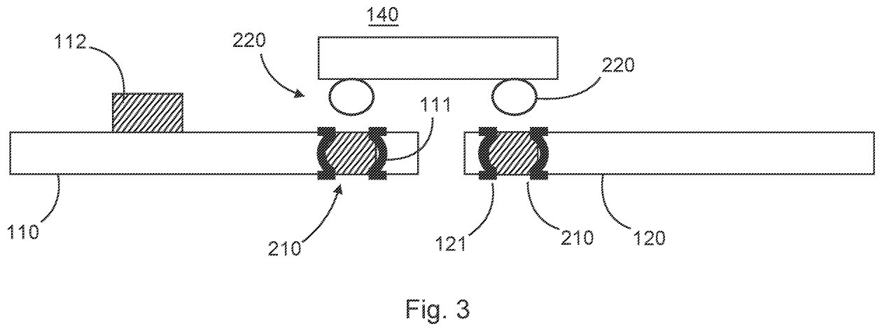

FIG. 3 is a schematic sectional view of a printed circuit board unit according to a third exemplary embodiment,

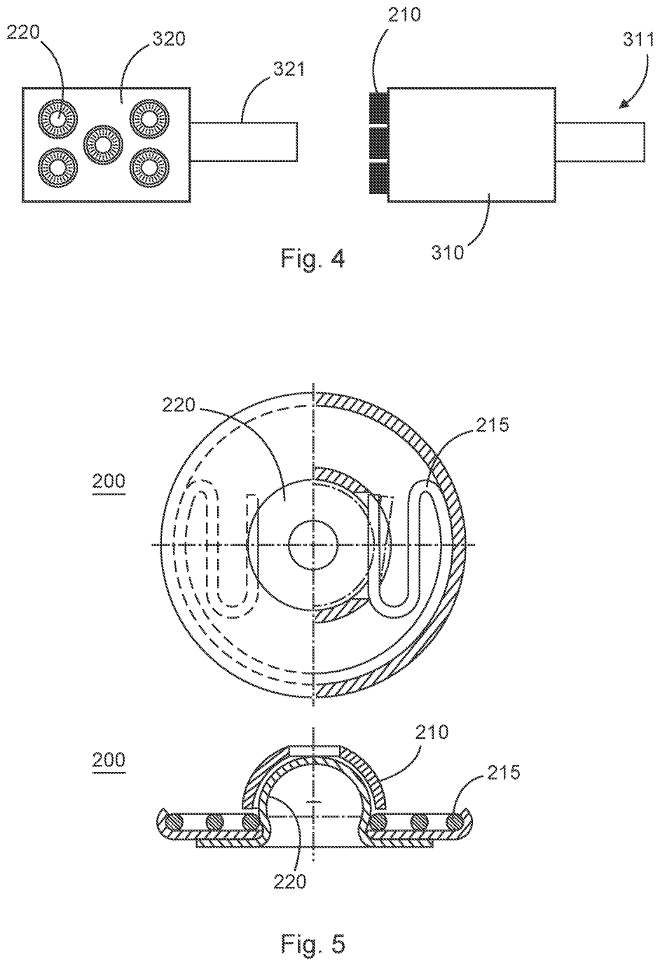

FIG. 4 is a schematic view of a plug according to a fourth exemplary embodiment,

FIG. 5 is a cross section and a sectional view of a push button according to one exemplary embodiment of the invention,

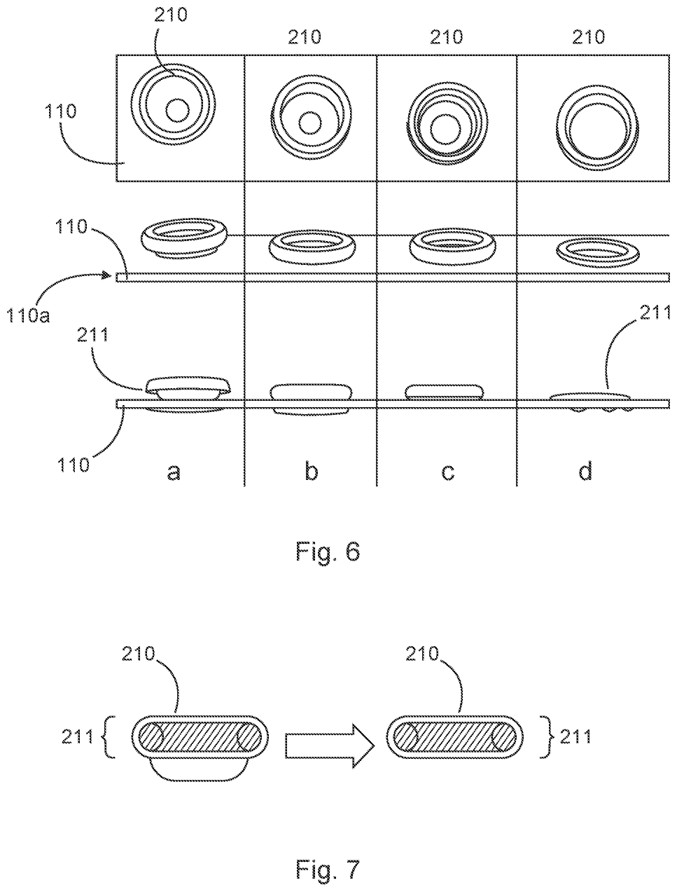

FIG. 6 is a schematic view of various first push button elements according to the invention,

FIG. 7 is a schematic view of a dish of a push button according to the invention,

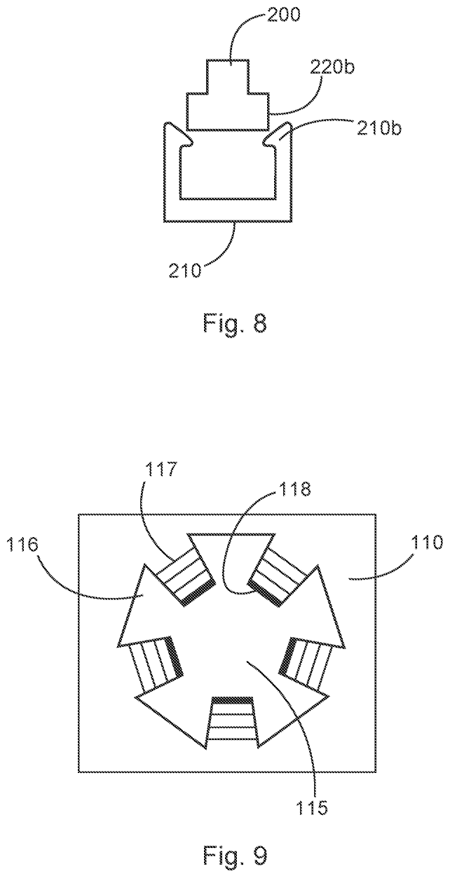

FIG. 8 is a schematic view of a connecting element, and

FIG. 9 is a schematic view of a printed circuit board.

FIG. 1 is a schematic view of a printed circuit board unit according to a first exemplary embodiment of the invention. The printed circuit board unit 100 has for example two printed circuit boards 110, 120. These two printed circuit boards 110, 120 are to be mechanically and/or electrically interconnected. This takes place by means of the connecting elements 200 which can be for example in the form of push buttons.

According to the first exemplary embodiment, push buttons are used as connecting elements for (mechanically and/or electrically) connecting e.g. two printed circuit boards. The push buttons each have a first and a second push button element, wherein a push button element is arranged in or on a first printed circuit board, and a second push button element is arranged in or on a second printed circuit board.

FIGS. 2A and 2B are each a schematic sectional view of a printed circuit board unit according to a second exemplary embodiment. According to the second exemplary embodiment, for example three printed circuit boards 110, 120, 130 are provided which are to be mechanically and/or electrically interconnected by means of connecting elements 200. The connecting elements 200 can be in the form of push buttons. The push buttons comprise a first push button element 210 having a depression or recess, and a second push button element 220 having a projection or head. For this purpose, the first printed circuit board 110 comprises a first push button element, e.g. a dish 210 of a push button 200. The second printed circuit board 120 has a head 220 on each side. The third printed circuit board has a first push button element, e.g. a dish 210.

The first and third printed circuit boards 110, 130 can be fixed to one another by means of the push button 200. For this purpose, the upper dish 210 merely has to be placed on the head 210. Furthermore, the lower dish 210 must be placed on the lower head.

According to the invention, the push button comprises a first push button element 210 having a recess, and a second element 220 having a projection. The first push button element 210 can be in the form of a dish. The second element 220 can be in the form of a head. The head is designed in such a way that it can be inserted in the first element 210 without being able to fall out thereof.

In FIG. 2B, the printed circuit board unit 100 is shown in the assembled state. In this case, the first printed circuit board 110 and the third printed circuit board 130 are mechanically and/or electrically connected to the second printed circuit board 120 by means of the push buttons 200.

In the first and second exemplary embodiments, what are known as board-to-board plug-in connectors are shown in each case. In this case, at least two printed circuit boards can be interconnected. The electrical connection by means of the push buttons can be used as ground potential.

FIG. 3 is a schematic sectional view of a printed circuit board unit according to a third exemplary embodiment. In FIG. 3, the two printed circuit boards 110, 120 are to be mechanically and/or electrically interconnected by means of a bridge in the form of a printed circuit board 140. Electronic components 112 can be provided on the printed circuit boards 110, 120, 130, 140. Connecting elements 200 are used to connect the printed circuit boards. In the exemplary embodiment from FIG. 3, the first and second printed circuit boards 110, 120 are arranged side-by-side. By contrast, for this purpose, the three printed circuit boards according to FIGS. 2A and 2B were arranged so as to be mutually parallel. The first printed circuit board 110 comprises a hole 111 having a dish 210, and the second printed circuit board 220 likewise comprises a hole 121 having a dish 210. Another printed circuit board 140, which is in the form of a bridge, comprises two heads 220. The distance between the two heads 220 is selected in such a way that the heads 220 can be placed in the dishes 210 when the first and second printed circuit boards 110, 120 are placed side-by-side.

A mechanical and/or electrical connection between two printed circuit boards can thus be achieved by means of a bridge printed circuit board 140.

FIG. 4 is a schematic view of a plug-in connector according to a fourth exemplary embodiment. The plug-in connector 300 comprises first and second portions 310, 320. In order to connect the first and second portions 310, 320, a plurality of connecting elements are provided e.g. in the form of push buttons 200. The push buttons 200 each have a first and second push button element 210, 220. The first push button elements 210 are arranged on the first portion 310, and the second push button elements 220 are arranged on the second portion 320. Alternatively or additionally, the first push button elements 210 can also be arranged on the second portion 320, and the second push button elements 220 can be arranged on the first portion 310. Alternatively, the first and second push button elements 210, 220 can each be arranged on both sides so that the first portion 310 comprises both first and second push button elements 210, 220, and the second portion 230 correspondingly comprises both second and first push button elements 220, 210. In order to mechanically and/or electrically connect the first and second portions 310, 320, the second push button elements 320 merely have to be placed in the first push button elements 310. The first and second portions 310, 320 of the plug-in connector 300 can each be connected by a cable 311, 321.

According to another aspect of the present invention, the first and/or second portion 310, 320 can be a printed circuit board or can be connected to a printed circuit board.

According to another aspect of the present invention, a printed circuit board can be coupled to a first and/or second portion 310, 320 of a plug-in connector for example by means of the connecting elements 200. By means of this connection, both energy and data can be exchanged. Furthermore, this connection can also be used as a ground connection.

FIG. 5 is a cross section and a sectional view of a push button according to one exemplary embodiment of the invention. The push button 200 comprises a first push button element 210 having a recess e.g. in the form of a dish, and a second push button element 220 in the form of a head. A spring 215 can optionally be provided in order to hold the head 220 in the dish in a better and more secure manner.

FIG. 6 is a schematic view of various first push button elements according to the invention. FIG. 6 shows four different portions a-d, showing a different integration of the first push button element 210 in a printed circuit board 111. In portion a, the height 211 of the first push button element is substantially greater than the thickness 110a of the printed circuit board. In portion d, the height 211 of the first push button element substantially corresponds to the thickness 210a of the printed circuit board. According to one aspect of the present invention, the height 211 of the first push button element 210 is 1 to 1.5 times the thickness 110a of the printed circuit board. In this case, it is optionally a flat or planar printed circuit board. The first push button elements 210 can be in the form of dishes having different dimensions (diameter, width, height). The height 211 of the dish 210 and the integration of the dish 210 in the printed circuit board 110 can be varied. The overall height can be affected thereby.

As can be seen in FIG. 6, portion d, the dish 210 can be integrated in the printed circuit board 110.

FIG. 7 is a schematic view of a dish of a push button according to the invention. The height 211 of the dish 210 can be reduced in order to reduce the overall height.

On the left-hand side of FIG. 7, a first push button element 210 is shown which is for example in the form of a dish. On the right-hand side, a first push button element 210 having a reduced height 211 is shown. This can be achieved for example by reducing the height of the dish or by removing the dish.

According to one aspect of the present invention, the first push button element 210 can be in the form of a female element, and the second push button element 220 can be in the form of a male element. In order to connect the printed circuit boards, the male element can be inserted in the female element and held therein.

According to one aspect of the present invention, a printed circuit board can be in the form of a flat, planar printed circuit board (PCB), in the form of a three-dimensional printed circuit board which has been produced in an injection-molding process (for example 2C injection molding) or in the form of a 3D MID printed circuit board.

According to one aspect of the present invention, a push button element can be integrated in the printed circuit board for example during the injection-molding process.

FIG. 8 is a schematic view of a connecting element according to another exemplary embodiment. The connecting element 200 can be for example in the form of a push button. The push button 200 comprises a first and second push button element 210, 220. The first push button element 210 can have a recess and an undercut 210b. The second element 220 can have a bead or a widening 220b of the diameter. The inside diameter of the undercut 210b is smaller than the outside diameter of the portion 220b. The undercut 210b can be in the form of a spring or a resilient contour. When the second element 220 is to be placed in the first element 210, then a certain amount of pressure must be overcome so that the bead 220b can get past the narrow point in the region of the undercut 210b. The second push button element 220 is then securely held in the first push button element 210.

FIG. 9 is a schematic view of a portion of a printed circuit board according to another exemplary embodiment. The printed circuit board 110 has an opening or hole 115 and a plurality of recesses 116 and spring elements 117 between adjacent recesses 116. By means of the recesses 116, the portions 117 with resilient properties can be obtained. The edges 118 of the hole which are still present can be provided for example with a conductive material so that the inwardly pointing edges of the portions 117 are each covered with an electrically conductive material. The first push button element can thus be produced. In particular, the first push button element is then integrated in the printed circuit board 110 and does not protrude or protrudes to only a limited extent. In this case, in particular a first push button element having a low overall height can be achieved.

List of reference signs

| | |
|---|---|
| 100 | printed circuit board unit |
| 110 | printed circuit board |
| 110a | thickness of the printed circuit board |
| 111 | hole |
| 112 | component |
| 115 | opening/hole |
| 116 | recess |
| 117 | spring elements |
| 118 | edge of the hole |
| 120 | printed circuit board |
| 121 | hole |
| 130 | printed circuit board |
| 140 | printed circuit board |
| 200 | connecting elements/push button |
| 210 | first push button element |
| 210a | thickness of the printed circuit board |
| 210b | undercut |
| 211 | height |
| 212 | height of first push button |
| 215 | spring |
| 220 | second push button |
| 220b | bead/widening |
| 230 | second portion |
| 300 | plug-in connector |
| 310 | first portion |
| 311 | cable |
| 320 | second portion |
| 321 | cable |

1. A printed circuit board unit, comprising at least one first and second printed circuit board and at least one first connecting element for mechanical and/or electrical connection between the at least one first and second printed circuit board,
wherein the connecting element is in the form of a push button.

2. The printed circuit board unit according to claim 1, wherein
the push button has a first and second push button element, wherein the first push button element is attached to the first or second printed circuit board, and the second push button element is attached to the second or first printed circuit board,
wherein the first and second push button elements are assembled in order to interconnect the first and second printed circuit boards.

3. The printed circuit board unit according to claim 1, wherein
a first connecting element has at least one first push button having a first dimension,
wherein a second connecting element has at least one push button having a second dimension, wherein the second dimension differs from the first dimension.

4. The printed circuit board unit according to claim 1, wherein the first push button element is in the form of a recess or dish, and
wherein the second push button element is in the form of a projection or head and is configured such that it can be connected to the first push button element.

5. The printed circuit board unit according to claim 1, wherein at least one of the printed circuit boards has a first push button element on a side of the printed circuit board and a second push button element on the other side of the printed circuit board,
wherein a first and third printed circuit board each have a first push button element and are configured in such that the two first push button elements of the first and third printed circuit boards can be connected to the two second push button elements of the second printed circuit board.

6. The printed circuit board unit according to claim 1, wherein the connecting element has an electrically conductive material at least in part so that the connecting element allows an electrical connection between the first and second printed circuit boards.

7. The printed circuit board unit according to claim 1, wherein the printed circuit boards are in the form of planar printed circuit boards, in the form of 3D printed circuit boards, produced in an injection-molding process, or in the form of 3D mechatronic integrated device printed circuit boards.

8. The printed circuit board unit according to claim 1, wherein a bridge printed circuit board is provided for mechanically and/or electrically connecting two printed circuit boards,
wherein the two printed circuit boards are arranged side-by-side,
wherein the bridge printed circuit board has a first or second push button element at each of the two ends thereof.

9. A printed circuit board connecting element, comprising
at least one push button which has a first and second push button element which can be interconnected,
wherein the first and second push button elements can be fixed in or on a printed circuit board.

10. The use of a push button as a connecting element for electrically and/or mechanically connecting at least a first and second printed circuit board.

11. A plug-in connector, comprising
a first and second plug-in connector portion and at least one push button configured for mechanically and/or electrically connecting the first and second plug-in connector portions.

12. The printed circuit board unit according to claim 2, wherein a first connecting element has at least one first push button having a first dimension. wherein a second connecting element has at least one push button having a second dimension, wherein the second dimension differs from the first dimension.

13. The printed circuit board unit according to claim 2, wherein the first push button element is in the form of a recess or dish, and
wherein the second push button element is in the form of a projection or head and is configured in such a way that it can be connected to the first push button element.

14. The printed circuit board unit according to claim 2, wherein at least one of the printed circuit boards has a first push button element on a side of the printed circuit board and a second push button element on the other side of the printed circuit board,
wherein a first and third printed circuit board each have a first push button element and are configured such that the two first push button elements of the first and third printed circuit boards can be connected to the two second push button elements of the second printed circuit board.

15. The printed circuit board unit according to claim 2, wherein the connecting element has an electrically conductive material at least in part so that the connecting element allows an electrical connection between the first and second printed circuit boards.

16. The printed circuit board unit according to claim 2, wherein the printed circuit boards are in the form of planar printed circuit boards, in the form of 3D printed circuit boards, produced in an injection-molding process, or in the form of 3D mechatronic integrated device printed circuit boards.

17. The printed circuit board unit according to claim 2, wherein a bridge printed circuit board is provided for mechanically and/or electrically connecting two printed circuit boards,
wherein the two printed circuit boards are arranged side-by-side,
wherein the bridge printed circuit board has a first or second push button element at each of the two ends thereof.

18. The printed circuit board unit according to claim 3, wherein the first push button element is in the form of a recess or dish, and
wherein the second push button element is in the form of a projection or head and is configured such that it can be connected to the first push button element.

19. The printed circuit board unit according to claim 3, wherein at least one of the printed circuit boards has a first push button element on a side of the printed circuit board and a second push button element on the other side of the printed circuit board,
wherein a first and third printed circuit board each have a first push button element and are configured such that the two first push button elements of the first and third printed circuit boards can be connected to the two second push button elements of the second printed circuit board.

20. The printed circuit board unit according to claim 3, wherein the connecting element has an electrically conductive material at least in part so that the connecting element allows an electrical connection between the first and second printed circuit boards.
